(19) United States
(12) Patent Application Publication
(10) Pub. No.: US 2010/0101647 A1
(43) Pub. Date: Apr. 29, 2010

(54) NON-AUTOCLAVE LAMINATION PROCESS FOR MANUFACTURING SOLAR CELL MODULES

(75) Inventors: Robert J. Cadwallader, Angier, NC (US); Rebecca L. Smith, Vienna, WV (US); Richard Allen Hayes, Beaumont, TX (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/603,067

(22) Filed: Oct. 21, 2009

Related U.S. Application Data
(60) Provisional application No. 61/108,153, filed on Oct. 24, 2008.

(51) Int. Cl. H01L 31/00; B29C 65/14

(52) U.S. Cl. 136/259; 156/273.7

(57) ABSTRACT

Disclosed is an improved non-autoclave lamination process for manufacturing solar cell modules, which combines a laminator and at least one pair of confronting nip rollers.

### CROSS-REFERENCE TO RELATED APPLICATION

This application claims priority to U.S. Provisional Application No. 61/108,153, filed on Oct. 24, 2008, which is incorporated herein by reference in its entirety.

### FIELD OF THE INVENTION

The invention relates to an improved non-autoclave lamination process useful for manufacturing solar cell modules.

### BACKGROUND OF THE INVENTION

Because they provide a sustainable energy resource, the use of solar cells is rapidly expanding. Solar cells are typically categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of self-supporting wafers (or cells) that are soldered together. The wafers generally have a thickness of between about 180 and about 240 μm. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for up to 25 to 30 years. In general, a solar cell module derived from wafer-based solar cell(s) comprises, in order of position from the front sun-facing side to the back non-sun-facing side: (1) an incident layer, (2) a front encapsulant layer, (3) a solar cell layer, (4) a back encapsulant layer, and (5) a backing layer.

The increasingly important alternative thin film solar cells are commonly formed from materials that include amorphous silicon (a-Si), microcrystalline silicon (μc-Si), cadmium telluride (CdTe), copper indium selenide (CuInSe₂ or CIS), copper indium/gallium diselenide (CuInGa₍₁₋ₓ₎Se₂ or CIGS), light absorbing dyes, and organic semiconductors. By way of example, thin film solar cells are disclosed in e.g., U.S. Pat. Nos. 5,507,881; 5,512,107; 5,948,176; 5,994,163; 6,040,521; 6,137,048; and 6,258,620 and U.S. Patent Publication Nos. 2007/0298590; 2007/0281090; 2007/0240759; 2007/0232057; 2007/0238285; 2007/0227578; 2007/0209699; and 2007/0079866. Thin film solar cells with a typical thickness of less than 2 μm are produced by depositing the semiconductor layers onto a superstrate or substrate formed of glass or a flexible film. During manufacture, it is common to include a laser scribing sequence that enables the adjacent cells to be directly interconnected in series, with no need for further solder connections between cells. As with wafer cells, the solar cell layer may further comprise electrical wirings such as cross ribbons and bus bars. Similarly, the thin film solar cells are further laminated to other encapsulant and protective layers to produce a weather resistant and environmentally robust module. Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a solar cell module derived from thin film solar cells may have one of two types of construction. The first type includes, in order of position from the front sun-facing side to the back non-sun-facing side, (1) a solar cell layer comprising a superstrate and a layer of thin film solar cell(s) deposited thereon at the non-sun-facing side, (2) a (back) encapsulant layer, and (3) a backing layer. The second type may include, in order of position from the front sun-facing side to the back non-sun-facing side, (1) an incident layer, (2) a (front) encapsulant layer, (3) a solar cell layer comprising a layer of thin film solar cell(s) deposited on a substrate at the sun-facing side thereof.

In addition, based on the material used in the incident layer and/or the backing layer, the solar cell modules can also be grouped into glass/glass type, glass/plastic type, plastic/plastic type, etc. In particular, a glass/glass type solar cell module refers to a type wherein both of the two outermost surface layers are formed of glass. For example, a glass/glass type solar cell module derived from wafer-based solar cells would comprise a solar cell layer sandwiched and encapsulated between two encapsulant layers, which are further sandwiched between a glass incident layer on the front sun-facing side and a glass backing layer on the back non-sun-facing side. On the other hand, a glass/glass type thin film solar cell module would have the semiconductor layers deposited on a glass substrate (or superstrate) and further laminated to an encapsulant layer and further to a glass incident (or backing) layer.

Various types of processes have been developed for manufacturing solar cell modules. One particular type of lamination process, which does not involve the use of autoclaves and is often referred to as “non-autoclave lamination process”, has been the subject of great interest in the past. Such a non-autoclave lamination process typically includes the steps of positioning all the component layers of the laminated structure to form a pre-lamination assembly and subjecting the assembly to heat, vacuum, and optionally pressure. See e.g., U.S. Pat. Nos. 3,234,062; 4,421,589; 5,238,519; 5,536,347; 5,759,698; 5,593,532; 5,993,582; 6,007,650; 6,134,784; 6,149,757; 6,241,839; 6,367,530; 6,369,316; 6,481,482; U.S. Patent Publication Nos. 2004/0182493; 2007/0215287, and PCT Patent Publication No. WO 2006/057771. Various types of laminators, such as the Meier ICOLAM® 10/08 laminator (Meier Vakuumtechnik GmbH, Bocholt, Germany), SPI-Laminators with model numbers 1834N, 1734N, 680N, 580 N, 580, and 480 (Spire Corporation, Bedford, Mass.), Module Laminators LM, LM-A and LM-SA series (NPC Incorporated, Tokyo, Japan), have been developed to perform the non-autoclave, or heat/vacuum lamination process. In particular, U.S. Pat. Nos. 5,593,532 and 6,369,316 disclose an improved non-autoclave lamination process wherein after undergoing the lamination process in a vacuum laminator, the module-stack (i.e., the pre-lamination assembly) is moved into a hardening oven to further harden the plastic sealing (i.e., encapsulant) layers. It is stated that such a process is useful when the encapsulant layers are formed of thermoset resins (e.g., poly(ethylene vinyl acetate) (EVA)) that require curing.

However, most of the commercially available laminators have only one heat source (e.g., a heated platen) positioned on one side (e.g., the bottom side) of the laminator chamber and consequently the assembly within the laminator chamber is heated from only one side. In such conditions, the assembly within the laminator chamber is often heated unevenly from only one side. In addition, the pressure that is applied to the assembly within the laminator (typically through use of an inflated bladder positioned on the top of the assembly) is often times not effective and therefore compromising the adhesion strength between the component layers in the resulting solar cell modules. There is still a need to develop an improved non-autoclave process for manufacturing solar cell modules having sufficient adhesion strength between the component layers.

### SUMMARY OF THE INVENTION

Disclosed herein is a process for preparing a solar cell module comprising: (A) subjecting a pre-lamination assembly to a vacuum force of about 1 to about 100 torr within a closed chamber, wherein one side of the assembly is exposed to a first heat source, the pre-lamination assembly is optionally heated to a temperature of about 25° C. or higher, and the pre-lamination assembly is maintained at said vacuum force and optional temperature condition for about 1 to about 15 minutes and wherein the pre-lamination assembly comprises (i) a solar cell layer comprising one or a plurality of electrically interconnected solar cells, the pre-lamination assembly having a front sun-facing side and a back non-sun-facing side and (ii) at least one encapsulant sheet layer that is positioned to one side of the solar cell layer; (B) increasing the temperature of the first heat source to heat the pre-lamination assembly to about 50° C. to about 150° C. while applying a pressure of about 1 atm to a surface of the pre-lamination assembly within the closed chamber, and maintaining the pre-lamination assembly at said vacuum, temperature, and pressure conditions for a period of time sufficient to achieve edge seal of the pre-lamination assembly; (C) releasing the vacuum force within the chamber and exposing the pre-lamination assembly to ambient pressure; (D) further exposing one or both sides of the pre-lamination assembly to a second heat source which heats the pre-lamination assembly to a temperature of about 70° C. to about 150° C. for about 1 to about 30 minutes; and (E) applying a pressure of about 5 to about 120 psi (about 0.035 to about 0.827 MPa) to the pre-lamination assembly by passing it through at least one pair of confronting pressing members to form the final solar cell module.

In one embodiment, steps (A)-(C) of the process are conducted within a vacuum laminator chamber wherein the first heat source is a heated platen positioned at one side of the vacuum laminator; and the second heat source used in step (D) is selected from the group consisting of forced air ovens, convection ovens, radiant heat sources, infrared light, microwave ovens, hot air, and combinations of two or more thereof.

In a further embodiment, step (D) of the process is conducted using a conveyor belt with the second heat source being one or more infrared lamps.

In a yet further embodiment, during step (B) of the process, the pre-lamination assembly is maintained at the vacuum, temperature, and pressure conditions for about 1 to about 8 minutes.

In a yet further embodiment, the at least one encapsulant sheet layer comprised in the pre-lamination assembly comprises a polymeric material selected from the group consisting of acid copolymers, ionomers of acid copolymers, poly(ethylene vinyl acetates), poly(vinyl acetals), polyurethanes, polyvinylchlorides, polyethylenes, polyolefin block copolymer elastomers, copolymers of α-olefins and α,β-ethylenically unsaturated carboxylic acid esters, silicone elastomers, epoxy resins, and combinations of two or more thereof.

In a yet further embodiment, the at least one encapsulant sheet layer comprised in the pre-lamination assembly comprises a thermoplastic polymer selected from the group consisting of acid copolymers, ionomers of acid copolymers, and combinations of two of more thereof.

In a yet further embodiment, the pre-lamination assembly further comprises an incident layer being an outermost surface layer of the assembly and positioned on the sun-facing side of the solar cell layer, and wherein the incident layer is selected from the group consisting of (i) glass sheets, (ii) polymeric sheets comprising a polymer selected from the group consisting of polycarbonates, acrylics, polyacrylates, cyclic polyolefins, polystyrenes, polyamides, polyesters, fluoropolymers, and combinations of two or more thereof, and (iii) polymeric films comprising a polymer selected from the group consisting of polyesters, polycarbonates, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, and combinations of two or more thereof.

In a yet further embodiment, the pre-lamination assembly further comprises a backing layer being an outermost surface layer of the assembly and positioned on the non-light receiving side of the solar cell layer, and wherein the backing layer is selected from the group consisting of (i) glass sheets, (ii) polymeric sheets comprising a polymer selected from the group consisting of polycarbonates, acrylics, polyacrylates, cyclic polyolefins, polystyrenes, polyamides, polyesters, fluoropolymers, and combinations of two or more thereof, and (iii) polymeric films comprising a polymer selected from the group consisting of polyesters, polycarbonates, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, and combinations of two or more thereof.

In a yet further embodiment, the solar cells comprised in the pre-lamination assembly are wafer-based solar cells selected from the group consisting of crystalline silicon (c-Si) and multi-crystalline silicone (mc-Si) based solar cells and the pre-lamination assembly consists essentially of, in order of position, (i) a glass incident layer, (ii) a front encapsulant layer positioned to the sun-facing side of the solar cell layer, (iii) the solar cell layer, (iv) a back encapsulant layer positioned to the non-light receiving side of the solar cell layer, and (v) a glass backing layer, wherein one or both of the front and back encapsulant layers comprises a thermoplastic polymer selected from the group consisting of acid copolymers, ionomers of acid copolymers, and combinations of two of more thereof.

In a yet further embodiment, the solar cells comprised in the pre-lamination assembly are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductor based solar cells, and the pre-lamination assembly consists essentially of, in order of position, (i) a glass incident layer, (ii) a front encapsulant layer comprising a thermoplastic polymer selected from the group consisting of acid copolymers, ionomers of acid copolymers, and combinations of two or more thereof, and (iii) the solar cell layer, which further comprises a glass substrate as an outermost layer of the assembly and upon which the thin film solar cells are deposited.

In a yet further embodiment, during steps (A)-(C) of the process, the pre-lamination assembly is positioned in such a way that the substrate side of the pre-lamination assembly is exposed to the heated platen; and during step (D), the pre-lamination assembly is positioned on the conveyor belt in such a way that the incident layer side of the pre-lamination assembly is exposed to the one or more infrared lamps.

In a yet further embodiment, the solar cells comprised in the pre-lamination assembly are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors based solar cells, and the pre-lamination assembly consists essentially of, in order of position, (i) the solar cell layer, (ii) a back encapsulant layer comprising a thermoplastic polymer selected from the group consisting of acid copolymers, ionomers of acid copolymers, and combinations of two or more thereof, and (iii) a glass backing layer, and wherein the solar cell layer further comprises a glass superstrate as an outermost layer of the assembly and upon which the thin film solar cells are deposited.

In a yet further embodiment, during steps (A)-(C) of the process, the assembly is positioned in such a way that the superstrate side of the pre-lamination assembly is exposed to a heating platen; and during step (D), the pre-lamination assembly is positioned on a conveyor belt with the second heat source being one or more infrared lamps positioned over the conveyor belt and the pre-lamination assembly is positioned in such a way that the backing layer side of the pre-lamination assembly is exposed to the one or more infrared lamps.

Also disclosed herein is a solar cell module manufactured by the process described above.

### BRIEF DESCRIPTION OF THE DRAWINGS

FIG. 1 is a cross-sectional view, not-to-scale, of a wafer-based solar cell module prepared by the process disclosed herein.

FIG. 2 is a cross-sectional view, not-to-scale, of one particular thin film solar cell module prepared by the process disclosed herein.

FIG. 3 is a cross-sectional view, not-to-scale, of another thin film solar cell module prepared by the process disclosed herein.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein. Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce those polymers or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers.

The term “acid copolymer” as used herein refers to a polymer comprising copolymerized units of an α-olefin, an β-ethylenically unsaturated carboxylic acid, and optionally other suitable comonomer(s) such as an α,β-ethylenically unsaturated carboxylic acid ester.

The term “ionomer” as used herein refers to a polymer that comprises ionic groups that are metal ion carboxylates, for example, alkali metal carboxylates, alkaline earth carboxylates, transition metal carboxylates and/or combinations of two or more of such carboxylates. Such polymers are generally produced by partially or fully neutralizing the carboxylic acid groups of a precursor or “parent” polymer that is an acid copolymer, as defined herein, for example by reaction with a base or a mixture of bases. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

Disclosed here is an improved non-autoclave lamination process for manufacturing a solar cell module. In particular, all the component layers of the solar cell module are first stacked in place to form a pre-lamination assembly and the final solar cell module is then obtained by having the thus-formed pre-lamination assembly undergo the improved non-autoclave lamination process, wherein the process may include at least five steps, a first step wherein the pre-lamination assembly is subjected to a vacuum force within a chamber, generally within a laminator having a heat source positioned on one side of the chamber; a second step wherein heat and pressure is applied to the pre-lamination assembly for a period of time sufficient to achieve edge seal of the pre-lamination assembly; a third step wherein the vacuum is released; a fourth step wherein the thus-treated pre-lamination assembly is heated to a temperature of at least 70° C. to about 150° C. at ambient pressure, and a fifth step wherein further pressure is applied to the pre-lamination assembly, generally by passing the assembly through at least one pair of nip rollers, to complete the lamination process.

The lamination process will comprise at least the following steps: (1) subjecting a pre-lamination assembly comprising a multilayer structure comprising a solar cell layer and a thermoplastic encapsulant sheet layer to a vacuum force of about 1 to about 100 torr, or about 1 to about 70 torr, or about 1 to about 50 torr, or about 2 to about 40 torr within a closed chamber, exposing a first side of the pre-lamination assembly to a first heat source, optionally heating the pre-lamination assembly to a temperature of about 25° C. or higher, or 25° to about 100° C., and maintaining the pre-lamination assembly under said vacuum and optional temperature conditions for about 1 to about 15 minutes, or about 5 to about 10 minutes; (2) increasing the temperature of the first heat source to heat the pre-lamination assembly to a temperature of about 50° C. to about 150° C., or about 50° C. to about 135° C., or about 70° C. to about 135° C. while applying a pressure of about 1 atmosphere to a surface of the pre-lamination assembly and maintaining the vacuum, temperature, and pressure conditions for an appropriate period of time sufficient to achieve edge seal, or for about 1 to about 8 minutes, or about 1 to about 5 minutes; (3) releasing the vacuum force and pressure and exposing the pre-lamination assembly to ambient pressure; and (4) removing the thus-treated pre-lamination assembly from the chamber and further exposing one or more sides of the pre-lamination assembly to a second heat source, which heats the assembly to a temperature of about 70° C. to about 150° C., or about 70° C. to about 135° C., or about 80° C. to about 135° C., or about 90° C. to about 135° C. for a period of about 1 to about 30 minutes; and (5) further applying a pressure of about 5 to about 120 psi (about 0.035 to about 0.827 MPa), or about 30 to about 100 psi (about 0.21 to about 0.69 MPa), or about 50 to about 100 psi (about 0.35 to about 0.69 MPa) to the pre-lamination assembly by passing it through at least one pair of confronting press members, e.g., nip rollers, to obtain a laminated solar cell module.

In steps (1) through (3), the pre-lamination assembly may be contained within a vacuum laminator chamber of any suitable type of laminator (such as the Meier ICOLAM® 10/08 laminator (Meier Vakuumtechnik GmbH, Bocholt, Germany), SPI-Laminators with model numbers 1834N, 1734N, 680N, 580 N, 580, and 480 (Spire Corporation, Bedford, Mass.), Module Laminators LM, LM-A and LM-SA series (NPC Incorporated, Tokyo, Japan), in which a heat source is located at one side, generally the bottom side of the lamination chamber. More particularly, the laminator may have a heated platen (e.g., an electrically heated platen) positioned at one side, generally the bottom side of the lamination chamber, and therefore the pre-lamination assembly will be heated by conductive heating from its bottom side. During step (2), the pressure may be applied to the pre-lamination assembly by an inflated bladder positioned on the top of the assembly. The duration of step (2) should be just sufficient to achieve sufficient edge seal on the pre-lamination assembly. By “sufficient edge seal” it is meant that the pre-lamination assembly has an about 5 to about 25 mm wide clear edge seal around its perimeter. In certain embodiments, to achieve sufficient edge seal, the duration of step (2) is about 1 to about 8 minutes, or about 1 to about 5 minutes.

Any of a variety of heat sources may be used as the second heat source in step (4) of the process. For example, the heat source may be an oven (e.g., forced air oven or convection oven) or a radiant heat source, such as infrared light (e.g, infrared light supplied by infrared lamps such as mid-wave infrared lamps), hot air, microwaves, or combinations thereof. During step (4), heat may be supplied to the pre-lamination assembly by heat sources positioned on one or more sides of the pre-lamination assembly. In one particular embodiment, step (4) of the process may be conducted while the assembly is transported on a conveyor belt with the assembly being heated from two sides (i.e., the top and bottom sides). In a further embodiment, the pre-lamination assembly is placed on a conveyor belt and heated only from one side, generally the side that is not in contact with the conveyor belt, by one or more infrared lamps. In a further embodiment, as an additional step prior to step (4), the pre-lamination assembly may be cooled following completion of step (3) but prior to being exposed to the second heat source in step (4). In a yet further embodiment, the process disclosed herein is a continuous process wherein the assembly is directly conducted to step (4) after the vacuum and pressure in the chamber have been released in step (3).

The press members used in the step (5) of the process may be confronting nip rollers (or “press rolls”), platen presses, or other press members that are adapted to apply pressure to the assembly. Confronting press members might be used here are a pair of confronting nip rollers, such as those disclosed in U.S. Pat. No. 7,143,800, or those manufactured by Billco Manufacturing, Inc. (Zelienople, Pa.), or Casso-Solar Corporation (Pomona, N.Y.). In certain embodiment, the heated pre-lamination assembly from step (4) is immediately moved on to step (5) so that the assembly still remains hot while being pressed. The pressure applied to the assembly is determined by the gap between each pair of the confronting press members and typically the gap between each pair of the confronting press members is smaller than the thickness of the assembly that is passed through. When series of pairs of press members are used, the gap between each pair of press members may be the same or adjusted to be gradually smaller toward the end of the process line.

Further disclosed herein is a solar cell module that is manufactured by the improved non-autoclave lamination process and comprises (a) a solar cell layer comprising one or a plurality of solar cells and (b) at least one encapsulant layer comprising a polymeric material selected from the group consisting of acid copolymers, ionomers of acid copolymers, poly(ethylene vinyl acetates), poly(vinyl acetals) (including acoustic grade poly(vinyl acetals)), polyurethanes, polyvinylchlorides, polyethylenes (e.g., linear low density polyethylenes), polyolefin block elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof.

In one embodiment, the encapsulant layer comprises a thermoplastic polymer selected from the group consisting of acid copolymers, ionomers of acid copolymers, and combinations thereof (i.e. a combination of two or more acid copolymers, a combination of two or more ionomers of acid copolymers, or a combination of at least one acid copolymer with one or more ionomers of acid copolymers). In particular, the acid copolymers used herein may be copolymers of an α-olefin having 2 to 10 carbons and an α,β-ethylenically unsaturated carboxylic acid having 3 to 8 carbons. For example, the acid copolymer may comprise about 18 to about 30 wt %, or 18 to about 25 wt %, or 20 to about 25 wt %, or about 21 to about 24 wt % of copolymerized units of the α,β-ethylenically unsaturated carboxylic acid, based on the total weight of the copolymer.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and combinations of two or more of such comonomers. In one embodiment, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and combinations of two or more thereof. In one embodiment, the α,β-ethylenically unsaturated carboxylic acid is selected from the group consisting of acrylic acids, methacrylic acids, and combinations of two or more thereof.

The acid copolymers may further comprise copolymerized units of other comonomer(s), such as unsaturated carboxylic acids having 2 to 10, or preferably 3 to 8 carbons, or derivatives thereof. Suitable acid derivatives include acid anhydrides, amides, and esters. In one embodiment, the acid derivatives used are esters. Specific examples of esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, dimethyl maleates, diethyl maleates, dibutyl maleates, dimethyl fumarates, diethyl fumarates, dibutyl fumarates, vinyl acetates, vinyl propionates, and combinations of two or more thereof. In certain embodiments, acid copolymers used herein may not comprise comonomers other than the α-olefins and the α,β-ethylenically unsaturated carboxylic acids.

The acid copolymers may be polymerized as disclosed in U.S. Pat. Nos. 3,404,134; 5,028,674; 6,500,888; and 6,518,365.

The acid copolymer may have a melt flow rate (MFR) of about 0.5 to about 1000 g/10 min, or about 0.5 to about 500 g/10 min, or about 1 to about 100 g/10 min, or about 1 to about 20 g/10 min, or about 1.5 to about 10 g/10 min, as determined in accordance to ASTM D1238 at 190° C. and 2.16 kg.

The ionomers of acid copolymers useful as components of the encapsulant layers are ionic, neutralized derivatives of precursor acid copolymers, such as those acid copolymers disclosed above. In one embodiment, the ionomers of acid copolymers are produced by neutralizing the acid groups of the precursor acid copolymers with a reactant that is a source of metal ions in an amount such that neutralization of about 10% to about 60%, or about 20% to about 55%, or about 35% to about 50% of the carboxylic acid groups takes place, based on the total carboxylic acid content of the precursor acid copolymers as calculated or measured for the non-neutralized precursor acid copolymers. Neutralization may often be accomplished by reaction of the precursor acid polymer with a base, such as sodium hydroxide, potassium hydroxide, or zinc hydroxide.

The metal ions may be monovalent ions, divalent ions, trivalent ions, multivalent ions, or combinations of two or more thereof. Useful monovalent metallic ions include, but are not limited to sodium, potassium, lithium, silver, mercury, and copper. Useful divalent metallic ions include, but are not limited to beryllium, magnesium, calcium, strontium, barium, copper, cadmium, mercury, tin, lead, iron, cobalt, nickel, and zinc. Useful trivalent metallic ions include, but are not limited to, aluminum, scandium, iron, and yttrium. Useful multivalent metallic ions include, but are not limited, to titanium, zirconium, hafnium, vanadium, tantalum, tungsten, chromium, cerium, and iron. It is noted that when the metallic ion is multivalent, complexing agents such as stearate, oleate, salicylate, and phenolate radicals may be included, as disclosed in U.S. Pat. No. 3,404,134. In one embodiment, the metal ions are monovalent or divalent metal ions. In a further embodiment, the metal ions are selected from the group consisting of sodium, lithium, magnesium, zinc, potassium and combinations of two or more thereof. In a yet further embodiment, the metal ions are selected from sodium, zinc, and combinations thereof. In a yet further embodiment, the metal ion is sodium.

The precursor acid copolymers may be neutralized as disclosed in U.S. Pat. No. 3,404,134.

The ionomers of acid copolymers useful as components of the encapsulant layers may have a MFR of about 0.75 to about 19 g/10 min, or about 1 to about 10 g/10 min, or about 1.5 to about 5 g/10 min, or about 2 to about 4 g/10 min, as determined in accordance with ASTM D1238 at 190° C. and 2.16 kg and the precursor acid copolymers, from which the ionomers of the acid copolymers are derived, may have a MFR about 0.5 to about 1000 g/10 min, or about 0.5 to about 500 g/10 min, or about 1 to about 100 g/10 min, or about 1 to about 20 g/10 min, or about 1.5 to about 10 g/10 min, as determined in accordance with ASTM D1238 at 190° C. and 2.16 kg.

The encapuslant layer composition may further contain one or more additives, such as processing aids, flow enhancing additives, lubricants, pigments, dyes, flame retardants, impact modifiers, nucleating agents, anti-blocking agents such as silica, thermal stabilizers, UV absorbers, UV stabilizers, hindered amine light stabilizers (HALS), silane coupling agents, dispersants, surfactants, chelating agents, coupling agents, reinforcement additives (e.g., glass fiber), and fillers.

The total thickness of each of the encapsulant layers may be in the range of about 1 to about 120 mils (0.026 to about 3 mm), or about 10 to about 90 mils (about 0.25 to about 2.3 mm), or about 15 to about 60 mils (about 0.38 to about 1.5 mm), or about 20 to about 45 mils (0.51 to about 1.1 mm).

Each of the encapsulant layer sheets may have a smooth or rough surface on one or both sides before it is laminated to the other component layers of the solar cell module. In one embodiment, the sheet has rough surfaces on both sides to facilitate deaeration during the lamination process.

The encapsulant layer sheet may be produced by any suitable process. For example, the sheets may be formed through dipcoating, solution casting, compression molding, injection molding, lamination, melt extrusion, blown film, extrusion coating, tandem extrusion coating, or by any other procedures that are known to those of skill in the art. In one embodiment, the sheets are formed by melt extrusion, melt coextrusion, melt extrusion coating, or tandem melt extrusion coating processes.

The term “solar cell” is meant to include any article which can convert light into electrical energy. Solar cells useful in the invention include, but are not limited to, wafer-based solar cells (e.g., c-Si or mc-Si based solar cells, as described above in the background section) and thin film solar cells (e.g., a-Si, μc-Si, CdTe, CIS, CIGS, light absorbing dyes, or organic semiconductor based solar cells, as described above in the background section). Within the solar cell layer, the solar cells may be electrically interconnected and/or arranged in a flat plane. In addition, the solar cell layer may further comprise electrical wirings, such as cross ribbons and bus bars. When in use, the solar cell layer has a “front sun-facing side” that faces the light source and a “back non-sun-facing side” that faces away from the light source. Therefore, when a solar cell module is assembled, the module or the pre-lamination assembly as a whole or any component layer thereof (i.e., the solar cell layer or the encapsulant layer) also has a “front sun-facing side” that, when in use, faces the light source and a “back non-sun-facing side” that, when in use, faces away from the light source. To allow efficient transmission of sunlight into the solar cells, the film or sheet layers positioned to the front sun-facing side of the solar cell layer are preferably made of transparent material.

The solar cell module manufactured by the improved non-autoclave lamination process typically comprises at least one encapsulant layer laminated to one side of the solar cell layer. By “laminated”, it is meant that, within a laminated structure, the two layers are bonded either directly (i.e., without any additional material between the two layers) or indirectly (i.e., with additional material, such as interlayer or adhesive materials, between the two layers). In one particular embodiment, the at least one encapsulant layer is directly laminated to one side of the solar cell layer.

The solar cell module may further comprise an incident layer and/or a backing layer serving as the outermost layer or layers of the module at the sun-facing side and the non-sun-facing side of the solar cell module, respectively.

The outer layers of the solar cell modules, i.e., the incident layer and the backing layer, may be derived from any suitable sheets or films. Suitable sheets may be glass or plastic sheets, such as polycarbonates, acrylics, polyacrylates, cyclic polyolefins (e.g., ethylene norbornene polymers), polystyrenes (preferably metallocene-catalyzed polystyrenes), polyamides, polyesters, fluoropolymers, or combinations of two or more thereof. In addition, metal sheets, such as aluminum, steel, galvanized steel, or ceramic plates may be utilized in forming the backing layer.

The term “glass” includes not only window glass, plate glass, silicate glass, sheet glass, low iron glass, tempered glass, tempered CeO-free glass, and float glass, but also colored glass, specialty glass (such as those containing ingredients to control solar heating), coated glass (such as those sputtered with metals (e.g., silver or indium tin oxide) for solar control purposes), low E-glass, Toroglas® glass (Saint-Gobain N.A. Inc., Trumbauersville, Pa.), Solexia™ glass (PPG Industries, Pittsburgh, Pa.) and Starphire® glass (PPG Industries). Such specialty glasses are disclosed in, e.g., U.S. Pat. Nos. 4,615,989; 5,173,212; 5,264,286; 6,150,028; 6,340,646; 6,461,736; and 6,468,934. It is understood, however, that the type of glass to be selected for a particular module depends on the intended use.

Suitable film layers comprise polymers that include but are not limited to, polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, and ethylene-tetrafluoroethylene copolymers), and combinations of two or more thereof. The polymeric film may be non-oriented, or uniaxially oriented, or biaxially oriented. Some specific exemplary films that may be used in the solar cell module outer layers (e.g., the incident layer or the backing layer) include, but are limited to, polyester films (e.g., poly(ethylene terephthalate) films), fluoropolymer films (e.g., Tedlar®, Tefzel®, and Teflon® films available from DuPont). Metal films, such as aluminum foil, may also be used as the backing layers. Further the films used in the solar cell module outer layers may be in the form of multilayer films, such a fluoropolymer/polyester/fluoropolymer (“TPT”) multilayer film.

The solar cell module may further comprise other functional film or sheet layers (e.g., dielectric layers or barrier layers) embedded within the module. Such functional layers may be derived from any of the above mentioned polymeric films or those that are coated with additional functional coatings. For example, poly(ethylene terephthalate) films coated with a metal oxide coating, such as those disclosed within U.S. Pat. Nos. 6,521,825 and 6,818,819 and European Patent No. EP1182710, may function as oxygen and moisture barrier layers in the laminates.

If desired, a layer of nonwoven glass fiber (scrim) may also be included between the solar cell layers and the encapsulants to facilitate deaeration during the lamination process or to serve as reinforcement for the encapsulants. The use of such scrim layers is disclosed, e.g., U.S. Pat. Nos. 5,583,057; 6,075,202; 6,204,443; 6,320,115; and 6,323,416 and European Patent No. EP0769818.

If desired, one or both surfaces of the incident layer films and sheets, the backing layer films and sheets, the encapsulant layers and other layers incorporated within the solar cell module may be treated prior to the lamination process to enhance the adhesion to other laminate layers. This adhesion enhancing treatment may take any form known within the art and includes flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 discloses a film or sheet with improved bondability, which has a thin layer of carbon deposited on one or both surfaces. Other exemplary adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

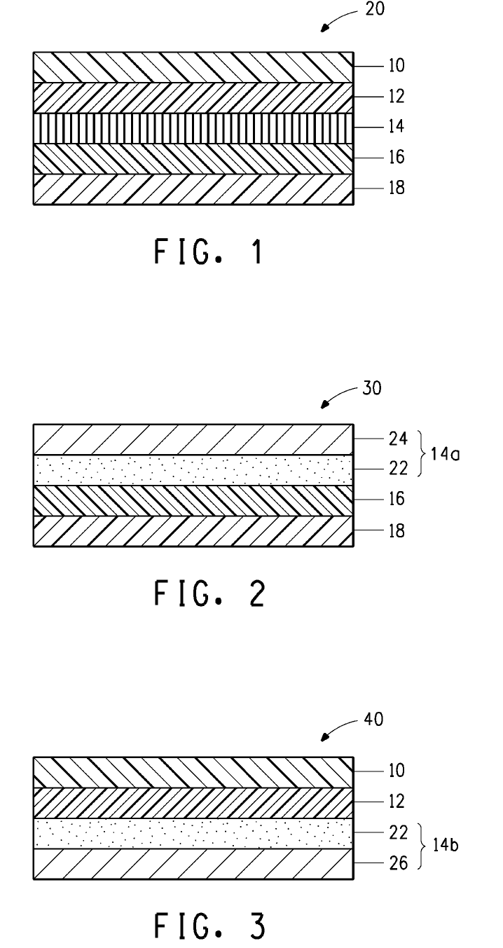

In one particular embodiment (now referring to FIG. 1), where the solar cells are derived from wafer-based self supporting solar cell units, the solar cell module (20) may comprise, in order of position from the front sun-facing side to the back non-sun-facing side, (a) an incident layer (10), (b) a front encapsulant layer (12), (c) a solar cell layer (14) comprised of one or more electrically interconnected solar cells, (d) a back encapsulant layer (16), and (e) a backing layer (18). In such an embodiment, both the incident layer (10) and the backing layer (18) may be formed of glass sheets and both the front and back encapsulant layers (12 and 16) may comprise the thermoplastic polymer (e.g., an acid copolymer, ionomer of an acid copolymer, or combination thereof) as disclosed above.

In a further embodiment (now referring to FIG. 2), where the solar cells are derived from thin film solar cells, the solar cell module (30) may comprise, in order of position from the front sun-facing side to the back non-sun-facing side, (a) a solar cell layer (14a) comprising a superstrate (24) and a layer of thin film solar cell(s) (22) deposited thereon at the non-sun-facing side, (b) a (back) encapsulant layer (16), and (c) a backing layer (18). In such an embodiment, both the backing layer (18) and the superstrate (24) may be formed of glass sheets and the back encapsulant layer (16) may comprise the thermoplastic polymer (e.g., an acid copolymer, ionomer of an acid copolymer, or mixture thereof) as disclosed above. During the lamination process, the pre-lamination assembly comprising all the component layers stacked in position may be placed in the laminator chamber with the superstrate side of the assembly facing the first heating source. For example, when the first heating source is a heated platen positioned at the bottom of the lamination chamber, the pre-lamination assembly is positioned in the laminator with the superstrate side of the assembly at the bottom. In a further embodiment, when only one side of the assembly is exposed to the second heating source used in step 4 of the process of the invention, the assembly may be positioned in such a way that the backing layer side of the assembly would face the second heat source. For example, when the second heating source is one or more infrared lamps positioned above a conveyor belt, the pre-lamination assembly is placed on the conveyor belt with the superstrate side at the bottom and the backing layer (e.g., a glass backing layer) facing the one or more infrared lamps.

In a yet further embodiment (now referring to FIG. 3), wherein the solar cells are also derived from thin film solar cells, the solar cell module (40) may comprise, in order of position from the front sun-facing side to the back non-sun-facing side, (a) a transparent incident layer (10), (b) a (front) encapsulant layer (12), and (c) a solar cell layer (14b) comprising a layer of thin film solar cell(s) (22) deposited on a substrate (26) at the sun-facing side thereof. In such an embodiment, both the incident layer (10) and the substrate (26) may be formed of glass and the front encapsulant layer may comprise a thermoplastic polymer (e.g., an acid copolymer, ionomer of an acid copolymer, or a combination thereof) as disclosed above. During the lamination process, the pre-lamination assembly comprising all the component layers stacked in position may be placed in the laminator chamber with the substrate side of the assembly facing the first heating source. For example, when the first heat source is a heated platen positioned at the bottom of the lamination chamber, the pre-lamination assembly may be placed in the chamber with the substrate side of the assembly at the bottom. In a further embodiment, when only one side of the assembly is exposed to the second heating source used in step 4 of the process of the invention, the assembly may be positioned in a way that the incident layer side of the assembly would face the second heat source. For example, when the second heating source is one or more infrared lamps positioned above a conveyor belt, the pre-lamination assembly is placed on the conveyor belt with the substrate side at the bottom and the incident layer (e.g., a glass sheet incident layer) facing the one or more infrared lamps.

Yet further disclosed here is a solar cell array comprising a series of the solar cell modules manufactured by the above described improved non-autoclave lamination process.

What is claimed is:

1. A process for preparing a solar cell module comprising:
(A) subjecting a pre-lamination assembly to a vacuum force of about 1 to about 100 torr within a closed chamber, wherein one side of the assembly is exposed to a first heat source, the pre-lamination assembly is optionally heated to a temperature of about 25° C. or higher, and the pre-lamination assembly is maintained at such vacuum and optional temperature condition for about 1 to about 15 minutes, and wherein the pre-lamination assembly comprises (i) a solar cell layer comprising one or a plurality of electrically interconnected solar cells, the pre-lamination assembly having a front sun-facing side and a back non-sun-facing side and (ii) at least one encapsulant sheet layer that is positioned to one side of the solar cell layer;
(B) increasing the temperature of the first heat source to heat the pre-lamination assembly to about 50° C. to about 150° C. while applying a pressure of about 1 atm to a surface of the pre-lamination assembly within the closed chamber, and maintaining the pre-lamination assembly at said vacuum, temperature, and pressure conditions for a period of time sufficient to achieve edge seal of the pre-lamination assembly;
(C) releasing the vacuum force within the chamber and exposing the pre-lamination assembly to ambient pressure;
(D) further exposing one or more sides of the pre-lamination assembly to a second heat source which heats the pre-lamination assembly to a temperature of about 70° C. to about 150° C. for about 1 to about 30 minutes; and
(E) applying a pressure of about 5 to about 120 psi (about 0.035 to about 0.827 MPa) to the pre-lamination assembly by passing it through at least one pair of confronting pressing members to form the solar cell module.

2. The process of claim 1, wherein steps (A)-(C) are conducted within a vacuum laminator chamber with the first heat source being a heated platen positioned at one side of the vacuum laminator; and wherein the second heat source used in step (D) is selected from the group consisting of forced air ovens, convection ovens, radiant heat sources, infrared light, microwave ovens, hot air, and combinations of two or more thereof.

3. The process of claim 2, wherein step (D) is conducted using a conveyor belt with the second heat source being one or more infrared lamps.

4. The process of claim 1, wherein during step (B), the pre-lamination assembly is maintained at the said vacuum, temperature, and pressure conditions for about 1 to about 8 minutes.

5. The process of claim 1, wherein the at least one encapsulant sheet layer comprises a polymeric material selected from the group consisting of acid copolymers, ionomers of acid copolymers, poly(ethylene vinyl acetates), poly(vinyl acetals), polyurethanes, polyvinylchlorides, polyethylenes, polyolefin block copolymer elastomers, copolymers of α-olefins and α,β-ethylenically unsaturated carboxylic acid esters, silicone elastomers, epoxy resins, and combinations of two or more thereof.

6. The process of claim 5, wherein the at least one encapsulant sheet layer comprises a thermoplastic polymer selected from the group consisting of acid copolymers, ionomers of acid copolymers, and combinations of two or more thereof.

7. The process of claim 6, wherein the pre-lamination assembly further comprises an incident layer being an outermost surface layer of the assembly and positioned on the sun-facing side of the solar cell layer, and wherein the incident layer is selected from the group consisting of (i) glass sheets, (ii) polymeric sheets comprising a polymer selected from the group consisting of polycarbonates, acrylics, polyacrylates, cyclic polyolefins, polystyrenes, polyamides, polyesters, fluoropolymers, and combinations of two or more thereof, and (iii) polymeric films comprising a polymer selected from the group consisting of polyesters, polycarbonates, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, and combinations of two or more thereof.

8. The process of claim 6, wherein the pre-lamination assembly further comprises a backing layer being an outermost surface layer of the assembly and positioned on the non-light receiving side of the solar cell layer, and wherein the backing layer is selected from the group consisting of (i) glass sheets, (ii) polymeric sheets comprising a polymer selected from the group consisting of polycarbonates, acrylics, polyacrylates, cyclic polyolefins, polystyrenes, polyamides, polyesters, fluoropolymers, and combinations of two or more thereof, and (iii) polymeric films comprising a polymer selected from the group consisting of polyesters, polycarbonates, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, and combinations of two or more thereof.

9. The process of claim 5, wherein the solar cells are wafer-based solar cells selected from the group consisting of crystalline silicon and multi-crystalline silicone based solar cells and wherein the pre-lamination assembly consists essentially of, in order of position, (i) a glass incident layer, (ii) a front encapsulant layer positioned to the sun-facing side of the solar cell layer, (iii) the solar cell layer, (iv) a back encapsulant layer positioned to the non-light receiving side of the solar cell layer, and (v) a glass backing layer, wherein one or both of the front and back encapsulant layers comprises a thermoplastic polymer selected from the group consisting of acid copolymers, ionomers of acid copolymers, and combinations of two or more thereof.

10. The process of claim 5, wherein the solar cells are thin film solar cells selected from the group consisting of amorphous silicon, microcrystalline silicon, cadmium telluride, copper indium selenide, copper indium/gallium diselenide, light absorbing dyes, and organic semiconductor based solar cells, and wherein the pre-lamination assembly consists essentially of, in order of position, (i) a glass incident layer, (ii) a front encapsulant layer comprising a thermoplastic polymer selected from the group consisting of acid copolymers, ionomers of acid copolymers, and combinations of two or more thereof, and (iii) the solar cell layer, which further comprises a glass substrate as an outermost layer of the assembly and upon which the thin film solar cells are deposited.

11. The process of claim 3, wherein during steps (A)-(C), the assembly is positioned in such a way that the substrate side of the pre-lamination assembly is exposed to the heated platen; and during step (D), the pre-lamination assembly is positioned on the conveyor belt in such a way that the incident layer side of the pre-lamination assembly is exposed to the one or more infrared lamps.

12. The process of claim 5, wherein the solar cells are thin film solar cells selected from the group consisting of amorphous silicon, microcrystalline silicon), cadmium telluride, copper indium selenide, copper indium/gallium diselenide, light absorbing dyes, and organic semiconductor based solar cells, and wherein the pre-lamination assembly consists essentially of, in order of position, (i) the solar cell layer, (ii) a back encapsulant layer comprising a thermoplastic polymer selected from the group consisting of acid copolymers, ionomers of acid copolymers, and combinations of two or more thereof, and (iii) a glass backing layer, and wherein the solar cell layer further comprises a glass superstrate as an outermost layer of the assembly and upon which the thin film solar cells are deposited.

13. The process of claim 12, wherein during steps (A)-(C), the assembly is positioned in such a way that the superstrate side of the pre-lamination assembly is exposed to the first heat source, wherein the first heat source is a heating platen; and during step (D), the pre-lamination assembly is positioned on a conveyor belt with the second heat source being one or more infrared lamps positioned over the conveyor belt and the pre-lamination assembly is positioned in such a way that the backing layer side of the pre-lamination assembly is exposed to the one or more infrared lamps.

14. A solar cell module manufactured by the process of claim 1.
